(19) United States
(12) Patent Application Publication
(10) Pub. No.: US 2021/0356180 A1
(43) Pub. Date: Nov. 18, 2021

(54) ELECTRONIC DEVICE COOLING SYSTEMS USING COOLED FLUID AND CONTROL OF SAME

(71) Applicant: GemaTEG Inc., Bellevue, WA (US)

(72) Inventors: Maurizio Miozza, Seattle, WA (US); Manfred Markevitch, Bellevue, WA (US); Marco Chiarappa, Corciano (IT); Dario Narducci, Milano (IT)

(21) Appl. No.: 17/318,873

(22) Filed: May 12, 2021

Related U.S. Application Data
(60) Provisional application No. 63/023,774, filed on May 12, 2020.

(51) Int. Cl. F25B 21/04; H05K 7/20

(52) U.S. Cl. CPC F25B 21/04; H05K 7/20272; H05K 7/20209; H05K 7/20281; H05K 7/20136

(57) ABSTRACT

Examples of systems described herein may be used to cool an electronic device. Systems include a heat exchanger in thermal communication with the electronic device. Fluid may be passed through the heat exchanger and heat transferred from the electronic device to the fluid at least in part using convection. A fluid cooling system may be provided to cool the fluid and provide cooled fluid back to the heat exchanger. The fluid cooling system may include an active cooler (e.g., a thermoelectric device) and one or more additional heat exchangers. Control systems may control a pump or fan used to propel fluid through the system and power to the active cooler to maintain a temperature of the electronic device to a desired temperature or range.

### CROSS-REFERENCE TO RELATED APPLICATIONS

This application claims the benefit under 35 U.S.C. § 119 of the earlier filing date of U.S. Provisional Application Ser. No. 63/023,774 filed May 12, 2020, the entire contents of which are hereby incorporated by reference in their entirety for any purpose.

### TECHNICAL FIELD

Examples described herein relate generally to thermal management of electronic devices. Examples of thermal management systems utilizing a cooled fluid are described.

### BACKGROUND

The growth in complexity of microelectronics has introduced new challenges for thermal management. Multicore microprocessors provide unparalleled computing power for critical applications (HPC=High-Performance Computing) at an unprecedented thermal heat flux above 20 W/cm². Similar considerations apply to power electronics and any other advanced field involving electronic systems. The need for a more compact design adds a layer of complexity, with the envelope becoming tighter at higher power density. For instance, the most common server configuration in HPC comes in 1U size, with a maximum height of 44.45 mm and a planar dimension slightly larger than the CPU. The new families of microprocessors will push these limits even further.

The available solutions for thermal management of high-power electronics are either gas or liquid cooling systems. Gas cooling systems have limited heat transfer capacity with unfavorable form factors but are economical and easy to deploy. Liquid cooling, either in a single or two-phase arrangement, are the preferred solution for high thermal dissipation power. Both technologies are mature with narrow margins of improvement. Extreme solutions, such as immersion cooling of the entire system in a dielectric fluid, address the current requirement but at high infrastructural and maintenance cost and significant safety issues.

### SUMMARY

Examples of systems are described herein. An example system may include a first heat exchanger configured to extract heat through convection from an electronic device. The first heat exchanger may at least partially define a cavity configured to pass a fluid from an inlet of the first heat exchanger to an outlet of the first heat exchanger. The first heat exchanger may further include structures in the cavity configured to alter a flow of the fluid. The example system may further include a temperature sensor configured to measure a temperature of the electronic device. The example system may further include a second heat exchanger configured to receive the fluid from the first heat exchanger. The second heat exchanger may be configured to cool the fluid. The example system may further include a thermoelectric device. A cold side of the thermoelectric device may be in thermal communication with the second heat exchanger. The example system may further include a fan or a pump configured to move the fluid from the first heat exchanger to the second heat exchanger. The example system may further include a control system configured to receive a signal indicative of the temperature of the electronic device. The control system may provide control signals to the fan or pump and electric power to the thermoelectric device based on the temperature to adjust a flow rate of the fluid and a heat transfer coefficient at the first heat exchanger.

In some examples, the temperature indicative of the electronic device may be a temperature of a case of the electronic device.

In some examples, the electronic device comprises a central processing unit (CPU).

In some examples, the structures in the cavity of a heat exchanger may include microchannels, walls, pins, pillars, protrusions, depressions, or combinations thereof.

In some examples, control system is configured to provide the control signals based on fluid boundary conditions in the first heat exchanger.

In some examples, the control system is configured to provide the control signals based on a thermal load on the electronic device.

In some examples, the control system is configured to adjust the heat transfer coefficient to promote heat exchange between the electronic device and the fluid.

In some examples, the fluid comprises a liquid, a gas, or combinations thereof.

In some examples, the thermoelectric device is configured to generate electrical power from the heat of the fluid.

In some examples, the fluid comprises a liquid and the pump or fan is a pump. In some examples, the fluid comprises a gas and the pump or fan is a fan.

In some examples, the control system is configured to regulate power to the thermoelectric device and a flow rate of the pump or fan.

In some examples, a material of the structures promotes thermal conductivity between the fluid and the structures.

In some examples, systems may further include a third heat exchanger, the third heat exchanger coupled to the hot side of the thermoelectric device.

In some examples, the second heat exchanger and the third heat exchanger have respective geometries configured to obtain a thermal impedance match.

Examples of methods are described herein. An example method may include providing a temperature signal to a controller. The temperature signal may be indicative of a temperature of an electronic device. The example method may further include adjusting a flow rate of a fluid used to cool the electronic device, power to a thermoelectric device configured to cool the fluid, or both, responsive to the temperature of the electronic device being outside one or more threshold values, to modify a heat transfer coefficient of a heat exchange device configured to contain the fluid such that the temperature of the electronic device changes toward the one or more threshold values.

In some examples, a method may further include activating a particular performance setting when the temperature of the electronic device exceeds an allowable threshold. The example method may further include triggering an alarm if temperature values maintain continue to exceed the allowable threshold.

In some examples, a method may include cooling the fluid using the thermoelectric device and circulating the fluid toward thermal contact with the electronic device.

In some examples, circulating may include flowing the fluid past structures in the heat exchange device, the structures configured to alter a flow of the fluid.

In some examples, a method may include generating electrical power with the thermoelectric device.

In some examples, a method may include providing exhausting waste heat from the thermoelectric device to an environment.

### BRIEF DESCRIPTION OF THE DRAWINGS

FIG. 1 is a schematic illustration of a system arranged in accordance with examples described herein.

FIG. 2 is a schematic illustration of a cross-sectional view of a heat exchanger arranged in accordance with examples described herein.

FIG. 3A and FIG. 3B are schematic cross-sections of example cavities in heat exchangers arranged in accordance with examples described herein.

FIG. 3C-FIG. 3E are schematic top-down views of example cavities in heat exchangers arranged in accordance with examples described herein.

FIG. 4 is a schematic illustration of a cross-section of a fluid cooling system arranged in accordance with examples described herein.

FIG. 5 is a schematic illustration of a cross-section of a fluid cooling system arranged in accordance with examples described herein.

FIG. 6 is a flowchart illustrating an example control methodology arranged in accordance with examples described herein.

### DETAILED DESCRIPTION

Thermoelectric devices offer various advantages for electronics thermal management, including reliability, compact envelope, fast response time, dual-purpose (e.g., cooling and power harvesting) and no moving parts. Thermoelectric modules generally refer to active devices that, once energized with electric power, act as a heat pump or, in the presence of a thermal gradient, harvest a portion of the heat flux and convert it into electrical energy. Conventional architectures, either with TEC on electronic devices or external, require higher electrical power to operate than traditional solutions, adding thermal load to the cooling system. Proper matching of the various elements introduces additional complexity to the overall architecture. Thus far, only low thermal load applications in niche sectors have benefited from the thermoelectric technology.

In general, gas or liquid loop cooling systems with or without thermoelectric modules, extract the thermal energy and transfer it to the surrounding environment, which may occur without control on the transfer fluid properties. Their reliance on the heat exchanger cooling power causes the size to increase with the thermal heat flux.

Examples described herein include systems incorporating an integrated approach to thermoelectric architecture to address high thermal flux electronic devices in a compact design. Examples operate with single-phase liquids or gas, creating an opportunity for thermal management in environments where liquids are not allowed. Examples described herein may include a heat recovery system that may increase the overall efficiency with the high-performance microprocessor.

Accordingly, examples described herein may provide systems and methods for cooling of electronic devices. Examples may include a fluid cooling system (e.g., an active pre-cooling chamber), a heat exchanger, and a control system which may implement an adaptive control methodology. The fluid cooling system may establish the fluid parameters with a thermoelectric device to achieve desired (e.g., optimal) performance with a particular workload at particular boundary conditions. The heat exchanger may be compact and in direct contact with the electronic device. The heat exchanger may be designed to maximize heat transfer in a reduced envelope (e.g., in a 1U server slot). Control systems may be closed-loop and may implement an adaptive control methodology which may continuously adjust the thermoelectric device current and/or the fluid flow rate to the actual workload. Example systems may be suitable for high thermal load devices, work with various fluids, such as water and air, and operate in a reduced envelope (e.g., a 1U server slot). In some examples, a recovery system may be included that harvests a portion of the waste heat and converts it into electrical energy.

Examples of systems described herein may utilize a control strategy for a heat transfer fluid used to extract heat from an electronic device. A fluid cooling system may set fluid properties based on the actual thermal load, the boundary conditions, and the electronic device characteristics. The fluid cooling system may include a thermoelectric module and two heat exchangers to maintain a desired (e.g., optimal) thermal gradient between the thermoelectric device surfaces. A closed-loop control system may constantly regulate the thermoelectric current and a motor (e.g., a fan or pump motor using PWM (Pulse-Width Modulation)) to compensate for the electronic device's thermal load variations. The control system may identify and/or store the system parameters for use at various conditions, which may allow for a fast response time at multiple boundary conditions and avoid and/or reduce transient temperature spikes in the electronic device. The pre-conditioned fluid flows through the heat exchange device in thermal communication (e.g., close contact) with the electronic device. The heat exchange device may include one or more structures (e.g., a microchannel architecture) which may reduce and/or minimize the form factor and increase (e.g., achieve maximum) transfer power. The geometry and/or structures of the heat exchange device may be selected to increase the heat transfer coefficient at low flow rates, which may increase heat transfer to the fluid. The fluid flows back to the cooling system for re-conditioning.

Certain details are set forth herein to provide an understanding of described embodiments of technology. However, other examples may be practiced without various of these particular details. In some instances, well-known thermoelectric device components, fluid control components, circuits, control signals, timing protocols, and/or software operations have not been shown in detail in order to avoid unnecessarily obscuring the described embodiments. Other embodiments may be utilized, and other changes may be made, without departing from the spirit or scope of the subject matter presented here.

Examples of systems described herein have a flexible topology, with the fluid cooling systems located in proximity to the electronic device being cooled in some examples, such as in a compact design suitable for a 1U server. In some examples, the fluid cooling system may be located in a remote location, such as in case of other envelope constraints.

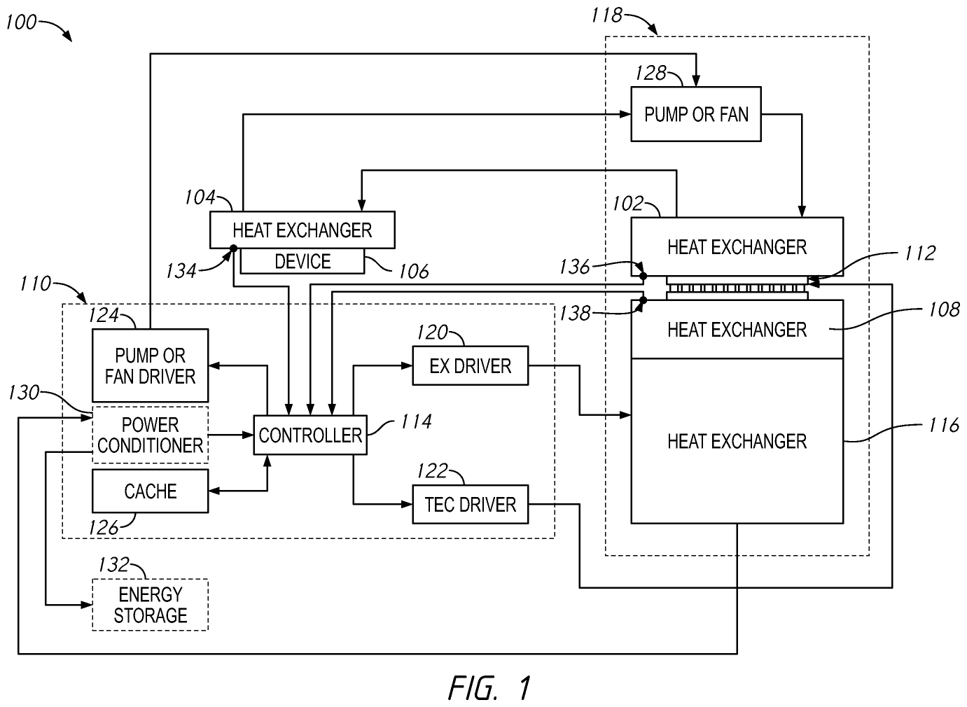

FIG. 1 is a schematic illustration of a system arranged in accordance with examples described herein. The system 100 is arranged to regulate a temperature of electronic device 106. The system 100 includes heat exchanger 104, temperature sensor 134, control system 110, and fluid cooling system 118. The fluid cooling system 118 may include pump or fan 128, heat exchanger 102, thermoelectric device 112, heat exchanger 108, heat exchanger 116, temperature sensor 136, and temperature sensor 138. The control system 110 may include controller 114, driver 124, driver 120, driver 122, and cache 126. In some examples, the control system 110 may include power conditioner 130. The power conditioner 130 may be coupled to energy storage 132. The components of FIG. 1 are exemplary. Additional, fewer, and/or different components may be included in other examples.

The heat exchanger 104 may be positioned to transfer heat from electronic device 106 into a fluid flowing through the heat exchanger 104. The fluid may flow from an output of the heat exchanger 104 to an input of heat exchanger 102. The pump or fan 128 may propel the fluid from the output of the heat exchanger 104 to the input of the heat exchanger 102. The heat exchanger 102 may cool the fluid, and cooled fluid may return from an output of the heat exchanger 102 to an input of the heat exchanger 104. In this manner, fluid may be remotely cooled using the fluid cooling system 118 and provided to the heat exchanger 104 to extract heat from the electronic device 106. In the fluid cooling system 118, the thermoelectric device 112 and heat exchanger 108 may be used to further control and/or regulate cooling of the fluid. In some examples, the heat exchanger 116 may further exhaust waste heat into an environment and/or capture heat for the generation of energy (e.g., power).

A control system 110 may be provided to provide closed-loop control of the fluid in the system 100. The temperature sensor 134 may measure a temperature of a portion of the heat exchanger 104 and/or electronic device 106. The temperature may be provided to controller 114. The temperature sensor 136 may measure a temperature of a portion of the heat exchanger 102. The temperature may be provided to controller 114. The temperature sensor 138 may measure a temperature of a portion of the heat exchanger 108. The temperature may be provided to controller 114. Controller 114 may be coupled to driver 120, driver 122, driver 124, and cache 126. The driver 120 may be coupled to the heat exchanger 116 to control operation of the heat exchanger 116. The driver 122 may be coupled to thermoelectric device 112 to control operation of the thermoelectric device 112. The driver 124 may be coupled to pump or fan 128 to control operation of pump or fan 128. The cache 126 may be coupled to the controller 114 and may store one or more values or software programs used by the power conditioner 130. In some examples, power conditioner 130 may be coupled to controller 114 and heat exchanger 116 and may be used to condition power generated by the heat exchanger 116. The power conditioner 130 may be coupled to energy storage 132 and may store some or all of the power or other energy generated by the heat exchanger 116 in the energy storage 132.

Examples of systems described herein accordingly may transfer heat from electronic devices, such as electronic device 106 of FIG. 1. Generally, heat may be transferred from any of a variety of electronic devices in accordance with techniques described herein. Examples of electronic devices include one or more central processing units (CPUs), graphics processing units (GPUs), processors, servers, circuitry (e.g., one or more transistors, resistors, inductors), solid state drives, batteries, and/or memory devices. The electronic device may be included in an assembly (e.g., case, package, system, device). The temperature of the assembly may be used to provide fluid control in some examples. In some examples, electronic devices cooled herein may have a small form factor (e.g., below 50 cm²) and high heat flow (e.g., >10 W/cm²). Examples of electronic devices described herein may find use in a wide array of systems. For example, aeronautical or astronautical systems may utilize electronic devices. For example, one or more satellites may include high-power electronics for communications. Excess waste heat may influence navigation and/or adjacent equipment. Satellite electronics may be cooled using systems described herein. Automotive systems may utilize electronic devices. For example, one or more batteries included in electric vehicles may experience heating, such as during particular phase(s) of the duty cycle. Systems described herein may be used to cool automotive batteries in some examples. Communication systems may utilize electronic devices. For example, high-power microwave equipment such as radars may generate heat, in part due to low conversion efficiency of electrical energy to microwave energy. Microwave equipment, such as radar equipment, may be cooled using systems described herein.

A heat exchanger may be provided to transfer heat from an electronic device, such as the heat exchanger 104 of FIG. 1. The heat exchanger 104 may extract heat from the electronic device 106 primarily using convection in some examples. The heat exchanger 104 may be in thermal contact with the electronic device 106. For example, a surface of the heat exchanger 104 may be positioned such that heat from the electronic device 106 (e.g., from circuitry and/or any portion of an assembly enclosing circuitry) may be transferred to the heat exchanger 104. In some examples, the heat exchanger 104 may be in direct contact (e.g., direct physical contact) with the electronic device 106. The heat exchanger 104 may have a cavity through which a fluid may flow. The heat exchanger 104 may have an inlet for providing fluid into the cavity, and an outlet for fluid exiting the cavity (and/or exiting the heat exchanger 104). A flow rate of the fluid through the heat exchanger 104 may be set by a control system described herein. Heat may be transferred by convection from the electronic device 106 to a fluid partially or wholly filling a cavity of the heat exchanger 104.

Heat exchangers described herein, such as heat exchanger 104, may accordingly define a cavity through which fluid may flow. Heat exchangers, such as heat exchanger 104, may include one or more structures positioned wholly or partially in the cavity which may alter a flow of the fluid. In some examples, fluid flow may be altered by the structures to create one or more eddies in a flow the fluid. Examples of structures include microchannels, walls, pins, pillars, protrusions, depressions, or other alterations in a cavity which may affect a flow of a fluid through the cavity. Generally, a material of walls of the cavity and/or a material of the structures (e.g., of which the cavity and/or structures are formed or of which the cavity and/or structures are wholly or partially coated) may be selected to promote heat transfer between the fluid and the structures. For example, one or more metals may be used to form the cavity and/or structures. Examples include aluminum, copper, or nickel.

In this manner, a fluid may be heated by an electronic device. For example, a fluid in a cavity of heat exchanger 104 may be heated as heat is transferred through convection from electronic device 106. Examples of systems described herein may include a cooling system, such as fluid cooling system 118, which may transfer heat from the fluid. In some examples, accordingly, the fluid may be cooled after being heated by heat transfer from an electronic device. The cooling system (e.g., fluid cooling system 118) may be remote from the electronic device. For example, the fluid cooling system 118 may not be in thermal communication with the electronic device 106 and/or heat exchanger 104. One or more tubes, channels, ducts, or other fluid transfer devices may connect heat exchanger 104 with the fluid cooling system 118 to move fluid between the heat exchanger 104 and the fluid cooling system 118.

Accordingly, in systems described herein, fluid may be used to transfer heat from an electronic device. The fluid may accordingly be heated. A fluid cooling system may be used to cool the fluid. The cooled fluid may again be circulated to the heat exchanger used to extract heat from the electronic device. Examples of fluids described herein may include liquids, gasses, or combinations thereof. Examples of fluids include distilled water, solutions including nanoparticles, glycol mixture(s), and/or phase change materials. Fluid may be propelled through the system (e.g., heated fluid from the heat exchanger 104 to the fluid cooling system 118 and/or cooled fluid from the fluid cooling system 118 to the heat exchanger 104) using a pump and/or a fan, such as pump or fan 128. Examples of liquids which may be used include, but are not limited to water. Examples of gasses which may be used include, but are not limited to, air, oxygen, nitrogen. In some examples, geometries of the heat exchanger 104, heat exchanger 102, and/or electronic device 106 may be selected based on the type of fluid (e.g., liquid or gas) being used.

Accordingly, systems described herein may generally include one or more pumps and/or one or more fans. For example, the pump or fan 128 of FIG. 1 may be used. While the pump or fan 128 is depicted as part of fluid cooling system 118, in some examples, the pump or fan 128 may be coupled to the heat exchanger 104 and the fluid cooling system 118. Generally, pump or fan 128 is used to circulate fluid from the heat exchanger 104 to the fluid cooling system 118 and back. Generally, in examples where the fluid is or includes a liquid, a pump may be used to implement pump or fan 128. In examples where the fluid is or includes a gas, a fan may be used to implement pump or fan 128. Note that in some examples pump or fan 128 is positioned on a path where heated fluid is being transferred from the heat exchanger 104 to the fluid cooling system 118. By positioning the pump or fan 128 in the path of the heated fluid (rather than in the path where cooled fluid is passed from the fluid cooling system 118 to the heat exchanger 104), the impact of possible heat or losses imposed by the pump or fan 128 may be reduced and/or avoided. For example, in such a configuration, waste heat from the pump or fan may have a lesser effect on the fluid in the heat exchanger 104. The pump or fan 128, however, may nonetheless provide a propelling force that propels a fluid from heat exchanger 104 to fluid cooling system 118 and from fluid cooling system 118 back to heat exchanger 104. In some examples, the pump or fan 128 may propel the fluid continuously from the fluid cooling system 118 to the heat exchanger 104 and back. In some examples, the pump or fan 128 may propel the fluid intermittently (e.g., pulsatile or other periodic flow may be used). The pump or fan 128 may include a motor. A speed of the motor may set a flow rate of the fluid in some examples. The motor may be controlled using pulse width modulation (PWM). Accordingly, the control system 110 may provide one or more PWM signals to the pump or fan 128.

Examples of systems described herein may include a fluid cooling system to cool fluid used to extract heat from electronic devices. The fluid cooling system may set fluid properties based on the actual thermal load, the boundary conditions, and the electronic device characteristics. In the example of FIG. 1, fluid cooling system 118 may be positioned to receive heated fluid from an output of the heat exchanger 104, cool the fluid, and provide cooled fluid to an input of the heat exchanger 104. Fluid cooling systems may include one or more heat exchangers and thermoelectric devices. In the example of FIG. 1, the fluid cooling system 118 includes heat exchanger 102 coupled to thermoelectric device 112. The thermoelectric device 112 may be in turn coupled to heat exchanger 108. The heat exchanger 102 may be positioned to receive fluid from heat exchanger 104 (e.g., the heat exchanger 102 may be coupled to heat exchanger 104 using one or more fluid passageways and/or one or more pumps or fans. Heated fluid may accordingly be provided to an inlet of the heat exchanger 102. The fluid may enter a cavity of the heat exchanger 102. The heat exchanger 102 may cool the fluid. The heat exchanger 102 may cool the fluid at least partially using convection. As described herein with reference to heat exchanger 104, the heat exchanger 102 may in an analogous manner contain a cavity and one or more structures positioned wholly or partially in the cavity. The structures may affect a flow of the fluid in the cavity, such as by causing one or more eddies in the fluid flow. The heat exchanger 102 may cool the fluid, such as by extracting heat from the fluid due to convection and/or thermoelectric mechanisms. The fluid cooling system 118 may be proximate the electronic device 106 in some examples (e.g., in a 1U server slot and/or in a server slot in a same rack as the electronic device 106). In some examples, the fluid cooling system 118 may be remote from the electronic device 106 (e.g., in a different rack than the electronic device 106 and/or distanced from the electronic device 106 such as in another device, and/or spaced apart in a room or other location).

To aid in cooling fluid, heat exchangers of a fluid cooling system described herein may be coupled to (e.g., in thermal communication with) one or more thermoelectric devices. For example, the heat exchanger 102 may be coupled to (e.g., in thermal communication with) the thermoelectric device 112. A thermoelectric device generally refers to a device that may provide a thermal difference from one side to another responsive to an applied energy (e.g., an applied voltage and/or current). The thermoelectric device 112 may accordingly have a cold side and a hot side. The cold side generally refers to a portion of the device which may have a lower temperature than another side of the device having a higher temperature. The difference in temperature between the hot side and the cold side may be based on an applied power (e.g., voltage and/or current). In some examples, an applied thermoelectric current may be set by the control system 110. The difference in temperature between the hot side and the cold side may in some examples be influenced by heat transfer from other devices to the hot and/or cold sides as well. Once energized (e.g., powered), the thermoelectric device 112 may reduce a temperature of the fluid being circulated in the system, transferring the heat to the heat exchanger 108 and through the heat exchanger 116 to the environment in some example

In some examples, electricity (e.g., power) may be generated in part due to a thermal difference between the hot and cold side of the thermoelectric device. For example, a thermoelectric device integrated in the heat exchanger 116 may be a thermoelectric generator used to generate electricity (e.g., power). In some examples, heat extracted from a fluid in heat exchanger 102 may be used to generate electricity by the thermoelectric device embedded in the heat exchanger 116. Generally, the thermoelectric device 112 may continue to be used for cooling of fluid, while another thermoelectric device integrated in heat exchanger 116 may perform heat recovery in some examples.

In the example of FIG. 1, the heat exchanger 102 may be coupled to (e.g., in thermal communication with) a cold side of the thermoelectric device 112. In this manner, heat may be extracted from heated fluid provided in and/or flowing through the heat exchanger 102. In some examples, another heat exchanger (e.g., heat exchanger 108 of FIG. 1) may be coupled to (e.g., in thermal communication with) the thermoelectric device, such as thermoelectric device 112. The heat exchanger 108 may be in thermal communication with the hot side of the thermoelectric device 112. As described herein with respect to heat exchangers, the heat exchanger 108 may have a cavity. A fluid may be present in and/or flowed through the cavity. One or more structures may be present in the cavity that may alter a flow of the fluid. In some examples, any fluid used in the heat exchanger 108 may be a different fluid than that circulated between heat exchanger 104 and fluid cooling system 118.

In some examples, the heat exchanger 102 and heat exchanger 108 have geometries and/or materials which may be selected for a thermal impedance match between the heat exchanger 102 and heat exchanger 108 and/or thermoelectric device 112. For example, a surface area of a side of the heat exchanger 108 facing the heat exchanger 102 may be selected to be equal to a surface area of a side of the heat exchanger 102 facing the heat exchanger 108. Generally, each component of the chain (e.g., heat exchanger 102, thermoelectric device 112, and heat exchanger 108) may have a specific thermal resistance ratio which may depend on the operating conditions and the configuration. For instance, based on the thermoelectric device 112 and its thermal resistance, the heat exchanger 102 and heat exchanger 108 may be provided with heat transfer coefficients which are equal and/or within a particular range and/or have a particular relationship with one another. This may facilitate heat flow in the system. Generally, the thermal resistance may depend on the geometry, flow rate, and heat load from the electronic device. Consider for a moment a parallel channel exchanger. The size of each channel determines at a specific flow rate the heat transfer coefficient (and/or its thermal resistance). The actual parameter is the hydraulic diameter, which may be equal to a ratio between area and surface of the channel section. Hydraulic diameter and flow rate combined may wholly or in part define the thermal resistance. In some examples, the geometry (e.g., hydraulic diameter) of the upper heat exchanger (e.g., heat exchanger 102) may be selected to be a fraction (e.g., half) of a value of the thermal resistance of thermoelectric device 112. Similar considerations apply to heat exchanger 108. Accordingly, the two heat exchangers, heat exchanger 102 and heat exchanger 108 may be used to maintain a desired (e.g., optimal) thermal gradient between the thermoelectric device 112 surfaces.

In some examples, thermoelectric device(s) in fluid cooling systems described herein may be operated wholly or partially as a generator. For example, using the Seebeck effect, the thermoelectric device embedded in the heat exchanger 116 may extract electrical power from heat. While commercial thermoelectric generator efficiency may be too modest, as the thermal gradient at the interfaces, to obtain substantial energy savings-however, some microprocessors present high heat flux. In some examples, such as examples where the electronic device 106 may be implemented using multiple microprocessors in one or more server racks, economy of scale may offset the generator's low efficiency.

In some examples, another heat exchanger, such as heat exchanger 116 of FIG. 1 may be coupled to the heat exchanger 108. The heat exchanger 116 may be used to exchange waste heat with the environment. In some examples, the heat exchanger 116 may provide electricity and/or energy generation based on the integrated thermoelectric generator. In some examples, an energy recovery system may be used to wholly and/or partially implement heat exchanger 116. The energy recovery system may include a thermoelectric generator that may convert all or portions of the heat flux from the heat exchanger 108 into electrical power. The amount of electrical power generated may depend on the thermal gradient between the thermoelectric generator's opposite surfaces and the heat load from the heat exchanger 108. In some examples, power conditioner 130 may transform the electrical power into signals and/or power suitable for storage in energy storage 132, such as a battery pack.

Systems described herein may include one or more temperature sensors. Temperature sensors may be provided to measure and/or monitor the temperature of certain components in the system. Components whose temperature may be monitored include an electronic device, one or more heat exchangers, the fluid, and/or the thermoelectric device or particular sides of the thermoelectric device. In the example of FIG. 1, the system 100 includes temperature sensor 134, temperature sensor 136, and temperature sensor 138. The temperature sensor 134 is positioned to measure a temperature of electronic device 106 and/or a side of the temperature sensor 134 facing the electronic device 106. The temperature sensor 136 is positioned to measure a temperature of a side of the heat exchanger 102 facing the thermoelectric device 112 (e.g., the cold side of the thermoelectric device 112). The temperature sensor 138 is positioned to measure a temperature of a side of the heat exchanger 108 facing the thermoelectric device 112 (e.g., the hot side of the thermoelectric device 112). Additional, fewer, and/or different temperature sensors may be used in other examples. In some examples, a temperature sensor may be positioned to measure a temperature of the fluid, for example at an input and/or output of heat exchanger 104 and/or heat exchanger 102.

Examples described herein may provide control of heat exchange using cooled fluids. For example, the rate of heat exchange and/or temperature of an electronic device, such as electronic device 106, may be controlled using control systems described herein. In some examples, the control system may set a flow rate of the fluid (e.g., by adjusting a motor speed) and/or may set a power to a thermoelectric device (e.g., by providing a particular thermoelectric current). The control system 110 may set an electric power to the thermoelectric device 112 and may set a flow rate of the pump or fan 128, taking into consideration the electronic device 106 characteristics, the temperature data from temperature sensor 134, temperature sensor 136, and/or temperature sensor 138, and/or the PWM duty cycle for the pump or fan 128 (e.g., as set by driver 124). In some examples, multiple temperature sensors may not be used. In some others only the temperature sensor 134 may be used as input to control system 110. In the example of FIG. 1, control system 110 includes controller 114, driver 124, driver 120, driver 122, and cache 126. Control systems may include one or more controllers, such as controller 114. Controllers may be implemented using, for example, one or more processors, microcontrollers, controllers, and/or circuitry. In some examples, a controller, such as controller 114 may additionally or instead be implemented using software and/or firmware. For example, computer readable media (e.g., memory, storage, read only memory (ROM), random access memory (RAM), solid state drive (SSD), cache 126) may be encoded with instructions which, when executed by a controller (e.g., processor) may perform control methodologies described herein. In some examples, the control system 110 may store parameters (e.g., flow rate(s), driver signals, PWM settings, and/or thermoelectric current settings) for particular boundary conditions—e.g., for particular loads (such as particular electronic devices) and/or temperatures. The parameters may be stored, for example in cache 126 or other memory accessible to the controller 114. During operation, the controller 114 may in some examples look-up parameters for use by the driver 124 and/or other drivers based on a thermal load and/or boundary conditions of the system 100.

Drivers may be used by the control system to provide a control signal to and/or influence performance of particular components. For example, the driver 124 maybe coupled to the pump or fan 128. The controller 114 may provide control signal(s) to driver 124, and the driver 124 may accordingly provide a signal to the pump or fan 128 to control operation of the pump or fan 128—e.g., to start, stop, and/or moderate a speed of the pump or fan 128. Controlling operation of the pump or fan 128 generally results in control of a flow rate of a fluid flowing between the heat exchanger 104 to the heat exchanger 102 and/or back. In some examples, the driver 124 may provide a pulse width modulated (PWM) signal to control and/or set a speed of a motor included in the pump or fan 128.

The driver 122 may be coupled to the thermoelectric device 112. The controller 114 may provide control signal(s) to the driver 122, and the driver 122 may accordingly provide a signal to the thermoelectric device 112 to control operation of the thermoelectric device 112. For example, the control signal may increase and/or decrease a current applied to the thermoelectric device 112 (and/or a voltage applied across the thermoelectric device 112), and may accordingly change a temperature difference between the hot and cold side of the thermoelectric device 112.

The driver 120 may be coupled to the heat exchanger 116. The controller 114 may provide control signal(s) to the driver 120. The driver 120 may in turn provide a signal to the heat exchanger 116 to set and/or change a rate of heat transfer to the environment. In some examples, the driver 120 may provide a signal to the heat exchanger 116 that may start, stop, and/or change a rate of electricity generation.

Accordingly, to provide control of heat exchange in the system, the controller 114 may receive one or more temperature signals from or proximate components of the system. For example, the controller 114 may receive a signal indicative of a temperature of an electronic device and/or a heat exchanger in thermal communication with the electronic device (e.g., from temperature sensor 134). In some examples, the controller 114 may additionally or instead receive signal(s) indicative of a temperature of one or more components of a fluid cooling system (e.g., of heat exchanger 102 and/or heat exchanger 108, such as from temperature sensor 136 and/or temperature sensor 138).

In this manner, control systems described herein may receive a signal indicative of a temperature of an electronic device. For example, the control system 110 may receive a signal indicative of a temperature of electronic device 106, such as a temperature from temperature sensor 134. The control system 110 (e.g., using controller 114) may compare the temperature to a desired temperature of the electronic device 106. The desired temperature may be stored in a memory or other electronic storage accessible to controller 114 (e.g., cache 126). In some examples, the desired temperature may be represented by one or more threshold values (e.g., a desired high temperature, a desired low temperature, and/or a desired average temperature). Based on the comparison, the control system 110 may provide one or more control signals to components of the system 100 to adjust the temperature closer to the desired temperature and/or within one or more of the threshold values. For example, the control system 110 may provide control signals to the pump or fan 128 and/or to the thermoelectric device 112 which may result in changes to the flow rate of the fluid and/or in a heat transfer coefficient at the heat exchanger 104 and/or heat exchanger 102. In this manner, overall heat transfer in the system may be adjusted. In some examples, a fluid temperature (e.g., as determined by power to thermoelectric device 112) and flow rate selected by the control system 110 may be selected to increase (e.g., maximizes) the heat transfer coefficient in the heat exchanger 104 at the electronic device 106 thermal load. A case temperature as measured by temperature sensor 134 may be controlled to remain below critical values (e.g., threshold values) regardless of the operating condition of the electronic device 106.

In some examples, control signals provided by the control system 110 (e.g., by controller 114 and/or any drivers of control system 110) may be based on fluid boundary conditions in the heat exchanger 104. For example, fluid dynamics occurring in the heat exchanger 104 may affect heat transfer to the fluid. The structures present in a cavity defined by the heat exchanger 104 may, for example, generate eddies or other fluid patterns that may affect the heat transfer. The controller 114 may utilize the anticipated fluid pattern to determine one or more control signals. In some examples, control signals provided by the control system 110 may additionally or instead be based on a thermal load at the electronic device 106. As the thermal load increases, a temperature of the electronic device 106 may increase. Accordingly, the controller 114 may increase a flow rate of the fluid and/or increase power to the thermoelectric device 112 to transfer more heat from the electronic device 106. Accordingly, the control system 110 may adjust a heat transfer coefficient between the fluid and one or more heat exchangers in the system (e.g., by adjusting a flow rate of the fluid and/or power to the thermoelectric device 112).

Accordingly, during operation, the control system 110 may receive one or more temperature signals of components in the system 100. The control system 110 may adjust a flow rate of the fluid circulating between heat exchanger 104 and fluid cooling system 118 and/or a power to thermoelectric device 112 when the temperature signals indicate the system performance is outside one or more threshold values. The adjustment of the flow rate and/or power may modify a heat transfer coefficient of the heat exchanger 104 and/or heat exchanger 102 which may contain the fluid. The adjustment may be made by the controller 114 and/or one or more drivers such that the temperature of the electronic device 106 and/or another component of the system moves toward the one or more threshold temperature s (e.g., desired temperature).

In some examples, a particular performance setting of the system 100 and/or control system 110 may be activated when the temperature of one or more components (E.g., a temperature of the electronic device 106 and/or heat exchanger 102 and/or heat exchanger 104 and/or heat exchanger 108) exceeds an allowable threshold. For example, the performance setting may be indicative of a more extreme adjustment setting to be made by the controller 114 using the drivers when the temperature is beyond an allowable threshold. If the temperature remains outside of a particular threshold range and/or exceeds an allowable threshold (either high or low) for greater than a particular amount of time (e.g., an amount of time stored in an area accessible to the controller 114, such as cache 126), the control system 110 may trigger an alarm. The alarm may be an audible, tactile, visual alarm and/or may include a communication (e.g., an email, phone call, text, SMS message, etc.). The controller 114 may trigger and provide the alarm, such as by providing an alarm signal to one or more displays, communication interface(s), speakers, and/or other output device(s) in communication with the controller 114 and/or control system 110.

Systems described herein may include one or more power generation and/or storage functionalities. For example, the heat exchanger 116 may generate electricity, for example based on integrated thermoelectric device. The control system 110 may in some examples include one or more power conditioners, such as power conditioner 130. The power conditioner 130 may be implemented, for example, using circuitry or other devices to condition power generated from the heat exchanger 116 and/or the embedded thermoelectric device. The controller 114 may provide one or more control signals to aid in conditioning the power. In some examples, the power conditioner 130 may provide signals to the controller 114 to maximize power generation. The power conditioner 130 may provide power to one or more energy storage devices, such as energy storage 132. The energy storage 132 may be implemented using, for example, one or more batteries.

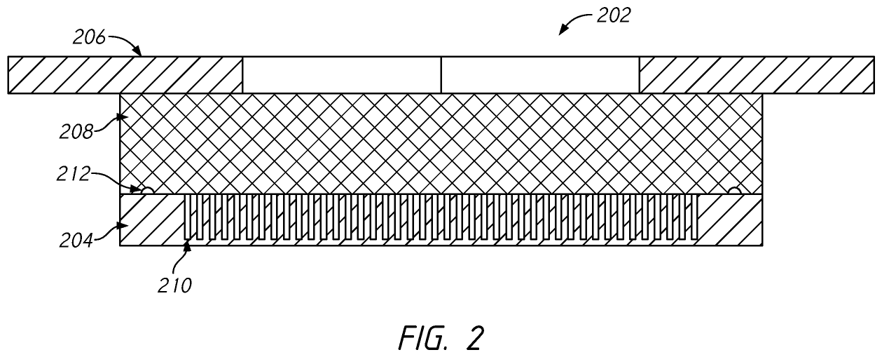

FIG. 2 is a schematic illustration of a cross-sectional view of a heat exchanger arranged in accordance with examples described herein. The heat exchanger 202 includes radiator block 204, cover plate 206, and insulating body 208. The radiator block 204 includes microchannels 210. An interface between insulating body 208 and radiator block 204 may be sealed using seal 212. The heat exchanger 202 may be used to implement and/or may be implemented by the heat exchanger 102, heat exchanger 104, and/or heat exchanger 108 of FIG. 1 in some examples. The components shown in FIG. 2 are exemplary only. Additional, fewer, and/or different components may be used in other examples.

The radiator block 204 at least partially defines a cavity that fluid may flow within. In the example of FIG. 2, a cross-section of microchannels is shown, although other structures may be used. The microchannel architecture may be advantageous due to the wide range of operating conditions, high thermal loads, and limited envelope, which may be presented by an electronic device to be cooled in accordance with examples described herein. In the microchannel architecture, overall surfaces may overlap standard microelectronic surfaces (e.g., 40×40 mm and higher). The structures (e.g., microchannels 210) may be formed and/or coated with high thermal conductivity material (e.g., thermal compound or pads). The section of FIG. 2 shows equally spaced straight channels. The microchannels may have sub-millimetric spacing in some examples. The use of microchannels (or other structures in other examples) may increase a surface area over which the fluid may transfer heat to the radiator block 204. Generally any microchannel geometries may be used, including straight, curved, intersecting, interrupted, and/or broken. Accordingly, the microchannel (or other structure) may be encapsulated in one or more thermally insulating layers.

A channel may be provided in insulating body 208 to accommodate a seal, such as seal 212. The seal 212 may be implemented using, for example an O-ring and/or a gasket. The seal 212 may reduce and/or prevent fluid leakage.

The cover plate 206 may secure the heat exchanger 202 to an electronic device to be cooled, such as electronic device 106 of FIG. 1.

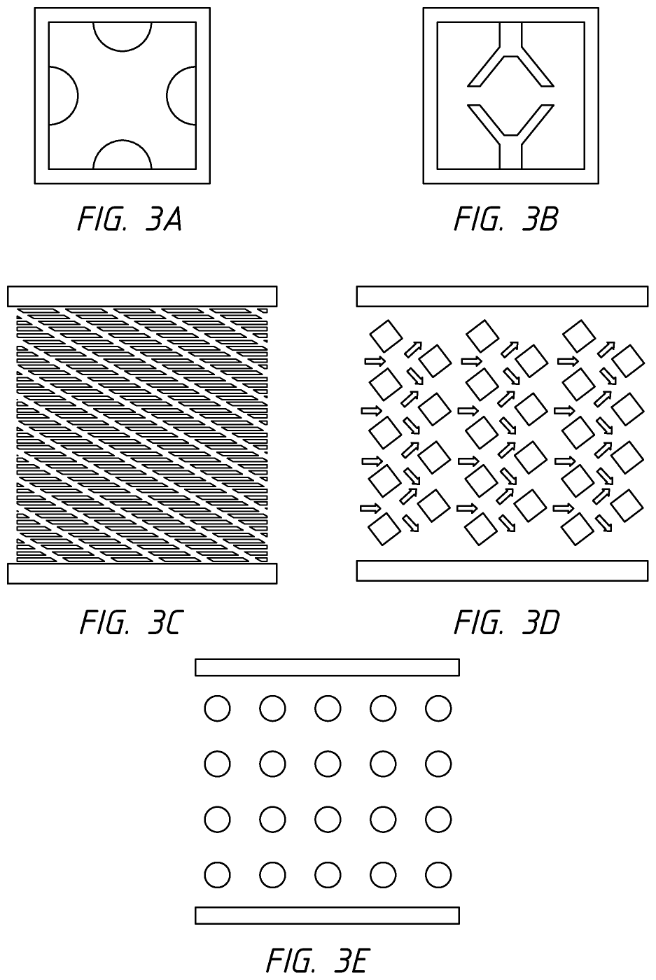

Examples of heat exchangers described herein may accordingly include one or more structures. The structures may alter the flow of the fluid within the cavity, such as by creating one or more eddies. Any of a variety of structures may be used. FIG. 3A and FIG. 3B are schematic cross-sections of example cavities in heat exchangers arranged in accordance with examples described herein. In the example of FIG. 3A, posts (e.g., pins) extending out from one or more walls of the cavity of a heat exchanger are provided. In the example of FIG. 3B, a V-shaped protrusion is provided extending out of at least one wall of the cavity, although more V-shaped protrusions from other walls may be used in other examples.

FIG. 3C-FIG. 3E are schematic top-down views of example cavities in heat exchangers arranged in accordance with examples described herein. FIG. 3C illustrates an arrangement of staggered lines of posts positioned within a cavity. FIG. 3D illustrates a shifted diamond shape posts positioned within a cavity, dividing fluid flow into multiple segments. FIG. 3E illustrates cylindrical pins within the cavity. Fluid flow may experience one or more eddies or other partially turbulent flow in the wide portions. Any of the examples of FIG. 3A-FIG. 3E may be used to implement heat exchangers described herein, such as heat exchanger 102, heat exchanger 104, and/or heat exchanger 108 of FIG. 1 in some examples.

It is to be understood that the arrangement, shape, and pattern of structures which may be disposed in the cavity may be quite flexible. Additionally, the wall shape of the various features may vary (e.g., may be straight and/or sloped). Generally, structures may be selected which may increase an amount of surface used to transfer heat from the device to the fluid and/or from the fluid to the device. However, the larger the surface, in some examples, the more friction the fluid may have at the channel walls. The fluid may then be slower, and the heat transfer process may become less efficient. Geometry and fluid speed (e.g., flow rates) are used herein to control heat transfer. In some examples, a larger pump or fan may be selected to further increase flow rates, however that may not be desirable in some examples due in part to larger size and/or larger power consumption.

In some examples, to design a cavity with structures, one or more cavity designs may be tested in a given system (e.g., with a particular electronic device and/or heat exchangers, and/or cooling system), and a particular structure arrangement may be selected from the candidate structures and/or a new arrangement selected based on thermal load and flow rate(s) in the system. In some examples, the structures may generate eddies that may increase the heat transfer in a similar manner as heat transfer is increased in a turbulent flow regime, however flow in the cavity may remain in a laminar flow regime. The increased heat transfer may occur even with a smaller heat transfer surface in some examples.

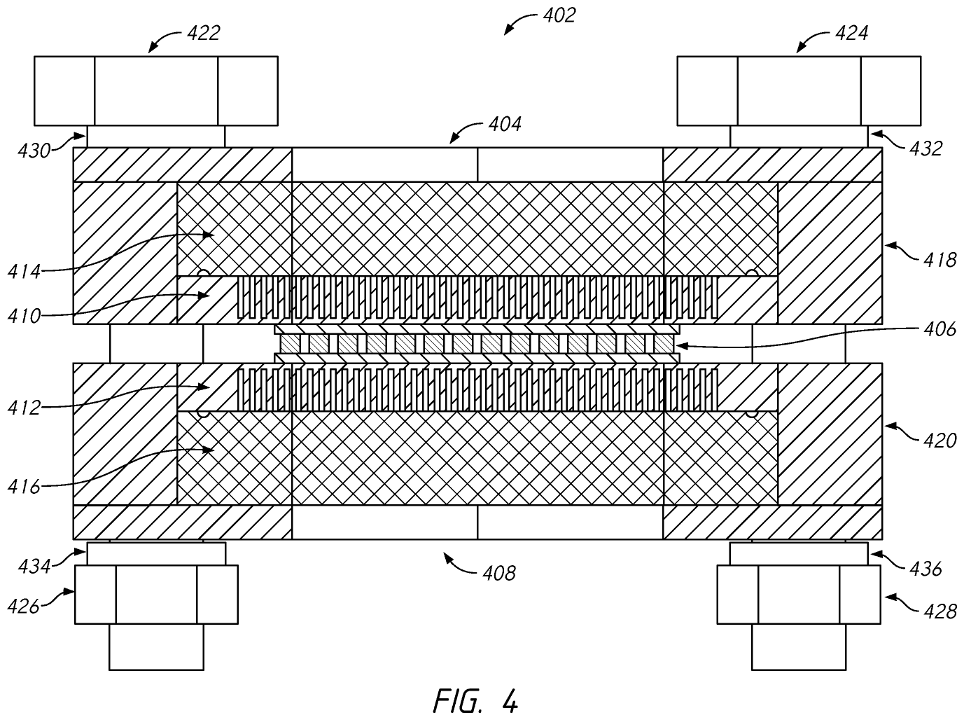

FIG. 4 is a schematic illustration of a cross-section of a fluid cooling system arranged in accordance with examples described herein. The fluid cooling system 402 includes an upper heat exchanger 404, a thermoelectric device 406, and a lower heat exchanger 408. The fluid cooling system 402 may be used to implement and/or may be implemented by the fluid cooling system 118 of FIG. 1 in some examples. For example, the heat exchanger 404 may be used to implement and/or may be implemented by heat exchanger 102. The heat exchanger 408 may be used to implement and/or may be implemented by heat exchanger 108. The thermoelectric device 406 may be used to implement and/or may be implemented by thermoelectric device 112. Moreover, the heat exchanger 404 and/or heat exchanger 408 may be used to implement and/or may be implemented by the heat exchanger 202 of FIG. 2 in some examples. The components shown in FIG. 4 are exemplary only. Additional, fewer, and/or different components may be used in other examples.

The upper heat exchanger 404 and lower heat exchanger 408 may include radiator blocks. For example, the heat exchanger 404 may include radiator block 410 and the heat exchanger 408 may include radiator block 412. The radiator blocks may define a cavity for fluid flow, and may include one or more structures (e.g., microchannels). The radiator blocks may be encapsulated in one or more insulating layers. The heat exchanger 404 and heat exchanger 408 may include insulating bodies (e.g., one or more layers of insulating material). For example, the heat exchanger 404 may include insulating body 414. The heat exchanger 408 may include insulating body 416. The insulating body may generally be provided between a radiator block and a cover. The insulating body may be implemented using, for example, one or more insulating materials such as acrylic glass, glass. Another insulating body and/or layer may be used to form an outer body of the heat exchangers. For example, the heat exchanger 404 may include insulating body 418 and the heat exchanger 408 may include insulating body 420. Each element's geometry may be selected to provide (e.g., optimize) thermal impedance matching while in some examples reducing (e.g., minimizing) the envelope of the fluid cooling system 402 at maximum expected device electronic thermal load.

The fluid cooling system 402 may be assembled using a compression method, which may be an example of a mechanical locking mechanism. The thermoelectric device 406 may be coupled to the heat exchanger 404 and heat exchanger 408 using compression members. For example, bolt 422 may be secured to nut 426 and bolt 424 may be secured to nut 428 at opposite ends of the assembly. Other numbers of bolts and/or nuts may be used in other examples.

Washers or other separators may be used to isolate components and reduce and/or prevent thermal short circuits. For example, the washer 430 may be positioned between bolt 422 and heat exchanger 404. The washer 432 may be positioned between bolt 424 and heat exchanger 404. The washer 434 may be positioned between nut 426 and heat exchanger 408. The washer 436 may be positioned between nut 428 and heat exchanger 408. The washers may be implemented using thermally insulating washers in some examples.

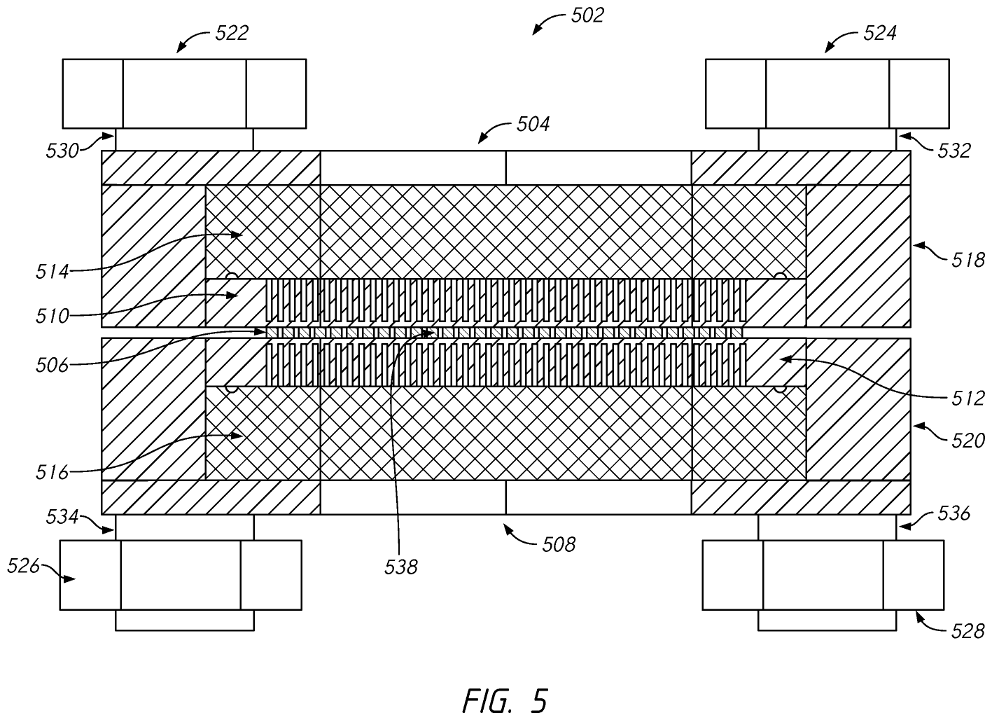

FIG. 5 is a schematic illustration of a cross-section of a fluid cooling system arranged in accordance with examples described herein. The fluid cooling system 502 includes an upper heat exchanger 504, a thermoelectric device 506, and a lower heat exchanger 508. The fluid cooling system 502 may be used to implement and/or may be implemented by the fluid cooling system 118 of FIG. 1 in some examples. For example, the heat exchanger 504 may be used to implement and/or may be implemented by heat exchanger 102. The heat exchanger 508 may be used to implement and/or may be implemented by heat exchanger 108. The thermoelectric device 506 may be used to implement and/or may be implemented by thermoelectric device 112. Moreover, the heat exchanger 504 and/or heat exchanger 508 may be used to implement and/or may be implemented by the heat exchanger 202 of FIG. 2 in some examples. The components shown in FIG. 5 are exemplary only. Additional, fewer, and/or different components may be used in other examples.

The upper heat exchanger 504 and lower heat exchanger 508 may include radiator blocks. For example, the heat exchanger 504 may include radiator block 510 and the heat exchanger 508 may include radiator block 512. The radiator blocks may define a cavity for fluid flow, and may include one or more structures (e.g., microchannels). The heat exchanger 504 and heat exchanger 508 may include insulating bodies (e.g., one or more layers of insulating material). For example, the heat exchanger 504 may include insulating body 514. The heat exchanger 508 may include insulating body 516. The insulating body may generally be provided between a radiator block and a cover. The insulating body may be implemented using, for example, one or more insulating materials such as acrylic glass, glass. Another insulating body and/or layer may be used to form an outer body of the heat exchangers. For example, the heat exchanger 504 may include insulating body 518 and the heat exchanger 508 may include insulating body 520. Each element's geometry may be selected to provide (e.g., optimize) thermal impedance matching while in some examples reducing (e.g., minimizing) the envelope of the fluid cooling system 502 at maximum expected device electronic thermal load.

The fluid cooling system 502 may be assembled using a compression method, which may be an example of a mechanical locking mechanism. The thermoelectric device 506 may be coupled to the heat exchanger 504 and heat exchanger 508 using compression members. For example, bolt 522 may be secured to nut 526 and bolt 524 may be secured to nut 528 at opposite ends of the assembly. Other numbers of bolts and/or nuts may be used in other examples.

Washers or other separators may be used to isolate components and reduce and/or prevent thermal short circuits. For example, the washer 530 may be positioned between bolt 522 and heat exchanger 504. The washer 532 may be positioned between bolt 524 and heat exchanger 504. The washer 534 may be positioned between nut 526 and heat exchanger 508. The washer 536 may be positioned between nut 528 and heat exchanger 508. The washers may be implemented using thermally insulating washers in some examples.

In the example of FIG. 5, the radiator block 510 and radiator block 512 may integrate the thermoelectric elements 538 directly on and/or in the interface surface. In this manner, a thermoelectric device insulating layer may not be used between the thermoelectric device 506 and heat exchanger 504 and/or heat exchanger 508. The architecture may increase (e.g., optimize) thermal impedance matching and utilize a variety of thermoelectric materials.

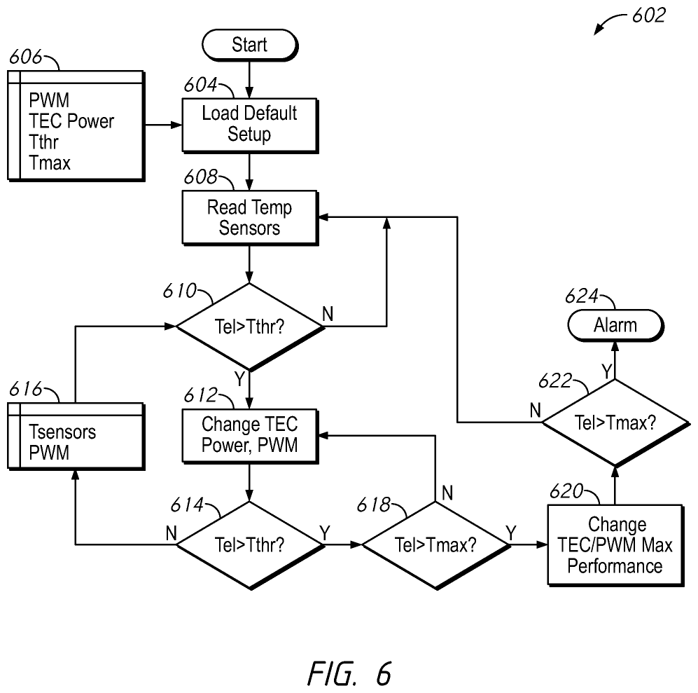

FIG. 6 is a flowchart illustrating an example control methodology arranged in accordance with examples described herein. The method shown in FIG. 6 may be implemented by one or more control systems described herein, such as control system 110 of FIG. 1 in some examples. For example, the control system 110 may include software (e.g., instructions encoded on one or more computer readable media) which may be executed by one or more processors (e.g., controller 114) to perform all or portions of the method shown in FIG. 6.

The method 602 may start in some examples in block 604. In block 604, a default setup may be loaded. For example, an initial thermoelectric power and/or motor control signal (e.g., PWM signal) may be loaded, e.g., from a memory accessible to controller 114 of FIG. 1, such as cache 126. Examples of data which may be stored, and which may be loaded in block 604 are shown as data 606. The data 606 may be stored in one or more memories, such as a memory accessible to the control system 110 (e.g., accessible to the controller 114 of FIG. 1). The data 606 includes PWM values (e.g., to control pump or fan 128). The data includes thermoelectric power (e.g., to control thermoelectric device 112 of FIG. 1). The data includes Tthr (e.g., a threshold temperature for initiating and/or stopping control). The data includes Tmax (e.g., a maximum allowable temperature). In some examples a calibration routine at first power-up of the system (e.g., of control system 110) may be used to define the initial parameters stored in the control system memory, such as one or more of the data 606.

In block 608, one or more temperature values may be read (e.g., received). For example, in the example of FIG. 1, the control system 110 (e.g., controller 114) may read and/or receive a temperature signal from temperature sensor 134. The temperature signal from temperature sensor 134 may be indicative of a temperature of electronic device 106 (e.g., a temperature of a case of electronic device 106). Additionally or instead, in block 608 temperature readings from other components may be made and/or received. For example, temperature values may be read from temperature sensor 136 and/or temperature sensor 138 of FIG. 1. Block 608 may occur after block 604 in some examples. In some examples, block 608 may occur wholly or partially simultaneous with block 604, and/or before block 604.

A temperature of a component may be compared to a threshold temperature in block 610. For example, the control system 110 of FIG. 1 (e.g., the controller 114) may compare a temperature of the electronic device 106 with a threshold temperature. The threshold temperature, Tthr, may have been loaded in block 604 in some examples. The threshold temperature may be set by a user, may be changed in some examples during operation, and/or may be set at a time of initial operation or formation of the system 100. If the temperature rises above the threshold and/or is equal to the threshold in some examples, the control system may enter a trimming loop mode of operation.

In a trimming loop mode of operation, in block 612, a power signal to a thermoelectric device and/or a control signal to a fan or pump may be adjusted. For example, the control system 110 of FIG. 1 may adjust control signal(s) to the thermoelectric device 112 and/or pump or fan 128. For example, a thermoelectric current signal provided by driver 122 may be adjusted. Additionally or instead, a PWM signal provided by the driver 124 may be adjusted. The adjustments to the thermoelectric power (e.g., current) and/or the motor control signals may be made to increase heat transfer to the fluid in the heat exchanger 104 and/or increase heat transfer out of the fluid in heat exchanger 102. The temperature may continue to be compared to the threshold, such as in block 614. When the temperature has dropped below the threshold temperature, the parameter values 616 (e.g., motor control signals such as PWM signals, and/or thermoelectric power signals such as thermoelectric current signals or values) may be stored. For example the controller 114 of FIG. 1 may store parameter values used at a time that the temperature of electronic device 106 was less than the threshold temperature. The values may be stored in a memory accessible to controller 114, such as in cache 126.

If the temperature, however, does not fall below the threshold, but continues to be above the threshold and/or rises further, the temperature may be compared with a maximum temperature value in block 618. For example, the control system 110 (e.g., the controller 114) may conduct the comparison. If the temperature has not exceeded the maximum temperature, control signals may continue to be adjusted in block 612, for example in a continued effort to bring the temperature below the threshold temperature. However, if the temperature has exceeded the maximum temperature and/or exceeded the maximum temperature for longer than a threshold amount of time, parameter values for maximum cooling capacity may be selected in block 620. For example, the control system 110 of FIG. 1 (e.g., the controller 114) may load and/or access parameters corresponding to maximum cooling capacity from memory. The controller 114 may then communicate with the drivers to provide control signals corresponding to maximum cooling operation to the pump or fan 128 and/or thermoelectric device 112.

Following operation with maximum cooling operation parameter values, the temperature is compared again with the maximum threshold in block 622. For example, the control system 110 (e.g., controller 114) of FIG. 1 may conduct the comparison. If the temperature has fallen below the maximum temperature value, the method may return to block 608 where temperature values are taken and compared with the threshold value (e.g., by control system 110). If the temperature continues to exceed the maximum threshold, in some examples for longer than a threshold time, an alarm may be provided in block 624. The alarm may be visual, tactile, auditory, and/or may include a communication message (e.g., email, phone call, text message, SMS message). The alarm may be provided, for example by the control system 110 such as by controller 114 using one or more output device(s) in communication with controller 114.

In a particular example, it may be desired to maintain a particular electronic device (e.g., a CPU) below 70° C. That may correspond to a temperature value taken from a case of the CPU by the temperature sensor 134 of FIG. 1 below 50° C. As the temperature reading climbs, control system 110, such as using driver 124 may change a control signal to the pump or fan 128, such as by changing a PWM duty cycle (going, for instance, from 30% to 50% in some examples). Additionally or instead, the control system 110, such as using driver 122, may modify the current to the thermoelectric device 112 (for example, from 2 A to 6 A). Additional changes may occur to the PWM and/or current to the TEC until the temperature stabilizes. Similar considerations apply when the temperature at temperature sensor 134 is way below the threshold. The control system 110 may adjust the PWM and current to the TEC to save energy. In some examples, the sensors at the opposite sides of the thermoelectric device 112 (e.g., temperature sensor 136 and temperature sensor 138) may be used to adjust the cooling power. In some examples, changes to the control signals may be based on how fast the temperature of one or more components is changing.

From the foregoing it will be appreciated that, although specific embodiments have been described herein for purposes of illustration, various modifications may be made while remaining with the scope of the claimed technology.

Examples have been described including an active liquid and/or gas cooling system for cooling fluid used to cool electronic devices. The cooling system may be implemented with or without energy harvesting capability. Example cooling systems described with reference, for example, to FIG. 1, utilize thermoelectric device(s) to provide active cooling. In other examples, however, technology other than thermoelectric may be used to provide active cooling for a fluid cooling system. The other active cooling technologies may similarly be controlled by control systems described herein.

Examples described herein may refer to various components as “coupled” or signals as being “provided to” or “received from” certain components. It is to be understood that in some examples the components are directly coupled one to another, while in other examples the components are coupled with intervening components disposed between them. Similarly, signal may be provided directly to and/or received directly from the recited components without intervening components, but also may be provided to and/or received from the certain components through intervening components.

What is claimed is:

1. A system comprising:
a first heat exchanger configured to extract heat through convection from an electronic device, the first heat exchanger at least partially defining a cavity configured to pass a fluid from an inlet of the first heat exchanger to an outlet of the first heat exchanger, the first heat exchanger further including structures in the cavity configured to alter a flow of the fluid;
a temperature sensor configured to measure a temperature of the electronic device;
a second heat exchanger configured to receive the fluid from the first heat exchanger, the second heat exchanger configured to cool the fluid;
a thermoelectric device, a cold side of the thermoelectric device in thermal communication with the second heat exchanger;
a fan or a pump configured to move the fluid from the first heat exchanger to the second heat exchanger;
a control system configured to receive a signal indicative of the temperature of the electronic device, the control system configured to provide control signals to the fan or pump and electric power to the thermoelectric device based on the temperature to adjust a flow rate of the fluid and a heat transfer coefficient at the first heat exchanger.

2. The system of claim 1, wherein the temperature of the electronic device comprises a temperature of a case of the electronic device.

3. The system of claim 1, wherein the electronic device comprises a central processing unit (CPU).

4. The system of claim 1, wherein the structures comprise microchannels, walls, pins, pillars, protrusions, depressions, or combinations thereof.

5. The system of claim 1, wherein the control system is configured to provide the control signals based on fluid boundary conditions in the first heat exchanger.

6. The system of claim 1, wherein the control system is configured to provide the control signals based on a thermal load on the electronic device.

7. The system of claim 1, wherein the control system is configured to adjust the heat transfer coefficient to promote heat exchange between the electronic device and the fluid.

8. The system of claim 1, wherein the fluid comprises a liquid, a gas, or combinations thereof.

9. The system of claim 1, wherein the thermoelectric device is configured to generate electrical power from the heat of the fluid.

10. The system of claim 1, wherein the fluid comprises a liquid and the pump or fan is a pump.

11. The system of claim 1, wherein the fluid comprises a gas and the pump or fan is a fan.

12. The system of claim 1, wherein the control system is configured to regulate power to the thermoelectric device and a flow rate of the pump or fan.

13. The system of claim 1, wherein a material of the structures promotes thermal conductivity between the fluid and the structures.

14. The system of claim 1, further comprising a third heat exchanger, the third heat exchanger coupled to the hot side of the thermoelectric device.

15. The system of claim 14, wherein the second heat exchanger and the third heat exchanger have respective geometries configured to obtain a thermal impedance match.

16. A method comprising:
providing a temperature signal to a controller, the temperature signal indicative of a temperature of an electronic device;
adjusting a flow rate of a fluid used to cool the electronic device, power to a thermoelectric device configured to cool the fluid, or both, responsive to the temperature of the electronic device being outside one or more threshold values, to modify a heat transfer coefficient of a heat exchange device configured to contain the fluid such that the temperature of the electronic device changes toward the one or more threshold values.

17. The method of claim 16 further comprising:
activating a particular performance setting when the temperature of the electronic device exceeds an allowable threshold; and
triggering an alarm if temperature values maintain continue to exceed the allowable threshold.

18. The method of claim 16, further comprising cooling the fluid using the thermoelectric device and circulating the fluid toward thermal contact with the electronic device.

19. The method of claim 16, wherein circulating comprises flowing the fluid past structures in the heat exchange device, the structures configured to alter a flow of the fluid.

20. The method of claim 16, further comprising generating electrical power with the thermoelectric device.

21. The method of claim 16, further comprising providing exhausting waste heat from the thermoelectric device to an environment.
